(19) United States
(12) Patent Application Publication
(10) Pub. No.: US 2008/0200002 A1
(43) Pub. Date: Aug. 21, 2008

(54) Plasma Sputtering Film Deposition Method and Equipment

(75) Inventors: Kenji Suzuki, Albany, NY (US); Taro Ikeda, Yamanashi (JP); Tatsuo Hatano, Yamanashi (JP); Yasushi Mizusawa, Albany, NY (US)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/577,535

(22) PCT Filed: Oct. 18, 2005
(86) PCT No.: PCT/JP2005/019120

§ 371 Date: Jan. 16, 2008

(30) Foreign Application Priority Data
Oct. 19, 2004 (JP) 2004-304922

(51) Int. Cl. H01L 21/02; H01L 21/44; C23C 14/34

(52) U.S. Cl. 438/381; 438/672; 204/298.02; 257/E21.022; 257/E21.476

(57) ABSTRACT

A method for generating metal ions by sputtering a metal target (56) by plasma, attracting the metal ions by bias power to a target object S which is to be processed and is mounted on a mounting table (20) in a processing vessel, and depositing a metal film (74) on the target object having a recess (2) thus filling the recess. The bias power is set to realize such a state as the metal deposition rate by attraction of metal ions is substantially balanced with the etching rate of plasma sputter etching on the surface of the target object. Consequently, the recess in the target object can be filled with metal without causing such a defect as void.

### FIELD OF THE INVENTION

The present invention relates to an improvement of a technique for burying a metal in a recess opened at the surface of a target object such as a semiconductor wafer by using plasma sputtering.

### BACKGROUND OF THE INVENTION

In general, various processes such as a film forming process and a pattern etching process are repetitively performed on a semiconductor wafer to manufacture a desired semiconductor device. With a demand for a higher level of integration and miniaturization of semiconductor devices, line widths and hole diameters are getting finer. With the miniaturization of such dimensions, electric resistances of a wiring material and a burying material are also required to be reduced, so copper having a small electric resistance and featuring a low price has been widely used as the wiring material or the burying material (see, Japanese Patent Laid-open Application No 2000-73655). When the copper is used as the wiring material or the burying material, a tantalum metal film, a tantalum nitride film or the like is generally utilized as an underlying barrier layer, in consideration of, e.g., adhesivity therebetween or the like.

When burying copper in a recess such as a groove or a hole, a thin seed film made of a copper film is first formed on the entire surface of a wafer, including the entire inner surface of the recess, in a plasma sputtering apparatus. Then, a copper plating process is performed on the entire wafer surface, the recess is filled with copper. Thereafter, the thin copper film remaining on the surface of the wafer is removed by a polishing process such as a chemical mechanical polishing (CMP) process.

The aforementioned conventional recess filling method will be described in detail with reference to FIGS. 8A to 8C. A plurality of recesses 2 are formed on a semiconductor wafer S, the recess being opened at the top surface of the wafer. The recesses 2 are via holes, through holes, grooves (trenches or dual damascene structures), and the like. As design rules are miniaturized, aspect ratios of the recesses 2 are very high (e.g., about 3 to 4), while their widths or inner diameters are small (e.g., about 120 nm).

A barrier layer 4 made up of a laminated structure of a TaN film and a Ta film is previously formed on the entire wafer surface and the entire inner surface of each recess 2 in a substantially uniform manner (see FIG. 8A). Then, in the plasma sputtering apparatus, a seed film 6 made of, e.g., a thin copper film is formed on the wafer surface and the inner surface of each recess 2 (see FIG. 8B). When forming the seed film 6, a bias power of a high frequency voltage is applied to a semiconductor wafer side to attract of copper ions efficiently. Then, a metal film 8 made of a copper film is formed on the wafer surface by a ternary copper plating process, whereby the inside of the recess 2 is filled with the copper. Afterward the metal film 8, the seed film 6 and the barrier layer 4 remaining on the wafer surface are removed by polishing.

When performing a film formation in the plasma sputtering apparatus, by applying a bias power to the semiconductor wafer side as described above, the attraction of metal ions is facilitated resulting in an increase of a film forming rate. If the bias power is set to be excessively great, however, the wafer surface would be sputtered by ions of a inert gas such as an argon gas introduced in a processing vessel for plasma generation, which causes metal films deposited thereon to be removed. Thus, the bias power cannot be set great beyond a certain level.

When forming the seed film 6 made of the copper film, it is very difficult for the seed film to be attached to a lower sidewall area B1 of the recess 2, as shown in FIG. 8B. Accordingly, if the film forming process is continued until the seed film 6 is deposited in a sufficient thickness on the area B1, an overhang portion 10 is formed at the seed film 6 near the top opening portion of the recess 2, so that the opening area of the recess 2 is narrowed. Even if the plating process is performed in this state, the recess 2 may not be completely filled up, which results in a void 11.

In order to prevent the generation of the void 11, it is necessary to conduct a so-called ternary plating process, which is a very complicated and troublesome process requiring, e.g., multiple kinds of additives. Moreover, if the ternary plating process is performed, the thickness H1 of the metal film 8 formed on the top surface of the wafer becomes excessively great. Accordingly, a polishing work therefor takes a long time.

### SUMMARY OF THE INVENTION

It is, therefore, an object of the present invention to provide a technique for burying a metal in a recess opened at the surface of a target object, without accompanying such a defect as a void.

It is another object of the present invention to ease a plating process which may be performed after filling the recess.

It is still another object of the present invention to ease a surface polishing process which may be performed after the metal burying process and/or the plating process.

In accordance with a first aspect of the present invention there is provided a film forming method including the steps of: loading a target object on a mounting table in a vacuum processing vessel, the target object having a recess opened at a surface thereof; generating a plasma in the vacuum processing vessel and generating metal ions by sputtering a metal target by the plasma, the metal target being disposed in the vacuum processing vessel; and applying a bias power to the mounting table to attract the metal ions into the recess to be deposited therein, thereby filling the recess with the metal; wherein the bias power is set to a level which makes a deposition rate of a metal deposition by the attraction of the metal ions and an etching rate of a sputter etching by the plasma substantially balanced at the surface of the target object.

A plating process may be performed after the filling of the recess with the metal. Further, a polishing process for polishing and flattening the surface of the target object may be performed after the plating process.

The width or a diameter of the recess may be 100 nm or less, and the aspect ratio of the recess may be 3 or higher.

The metal may be copper, aluminum or tungsten.

Further, in accordance with the present invention, there is also provided a film forming method including: a loading process for loading a target object on a mounting table in a vacuum processing vessel, the target object having a recess opened at a surface thereof; a first film forming process including the steps of generating a plasma in the vacuum processing vessel and generating metal ions by sputtering a metal target by the plasma, the metal target being disposed in the vacuum processing vessel; and applying a bias power to the mounting table to attract the metal ions into the recess to be deposited therein, thereby filling the recess with the metal; and a second film forming process including the steps of generating a plasma in the vacuum processing vessel and generating metal ions by sputtering the metal target by the plasma; and applying a bias power to the mounting table to attract the metal ions into the recess to be deposited therein, thereby filling the recess with the metal wherein the first film forming process and the second film forming process are alternately repeated plural times and the bias power of the first film forming process is set to a level which makes a deposition rate of a metal deposition by the attraction of the metal ions much higher than an etching rate of a sputter etching by the plasma on the surface of the target object, and the bias power of the second film forming process is set to a level which makes the deposition rate of the metal deposition by the attraction of the metal ions and the etching rate of the sputter etching by the plasma substantially balanced at the surface of the target object.

It is preferable that the alternative repetition of the first and the second film forming process is completed by the first film forming process.

A plating process may be performed after repetitively performing the first and the second film forming process plural times. Further, a polishing process for polishing and flattening the surface of the target object may be performed after the plating process.

In an embodiment of the present invention, the target object is a substrate for an interposer connecting IC chips to each other.

Further, an induction coil may be formed by a metal film buried in the recess of the target object.

The metal may be copper, aluminum or tungsten.

In accordance with a second aspect of the present invention, there is provided a plasma processing apparatus including: a vacuum processing vessel to be evacuated; a gas introduction unit for introducing a gas into the processing vessel; a mounting table for mounting thereon a target object which has a recess opened at a surface thereof; a plasma generating device for generating a plasma in the processing vessel; a metal target disposed in the processing vessel, to be ionized by the plasma; a bias power supply for supplying a bias power to the mounting table; and a bias power supply controller for controlling the bias power supply, wherein the bias power supply controller controls the bias power output from the bias power supply to a level which makes a deposition rate of a metal deposition by the attraction of metal ions and an etching rate of a sputter etching by the plasma substantially balanced at the surface of the target object.

Further, in accordance with the present invention, there is also provided a plasma processing apparatus including: a vacuum processing vessel to be evacuated; a gas introduction unit for introducing a gas into the processing vessel; a mounting table for mounting thereon a target object which has a recess opened at a surface thereof; a plasma generating device for generating a plasma in the processing vessel; a metal target disposed in the processing vessel, to be ionized by the plasma; a bias power supply for supplying a bias power to the mounting table; and a bias power supply controller for controlling the bias power supply, wherein the bias power supply controller controls the entire plasma processing apparatus to perform a process for activating the gas to generate the plasma and generating metal ions by sputtering the metal target by the plasma and a process for filling the recess with a metal film by applying a bias voltage which makes a deposition rate of a metal deposition by an attraction of the metal ions and an etching rate of a sputter etching by the plasma substantially balanced.

In accordance with the present invention, it is possible to fill recesses of a target object efficiently by adjusting a relation between a deposition rate of a metal film by an attraction of metal ions and an etching rate of a sputter etching by a plasma, by means of controlling a bias power applied to a mounting table.

### BRIEF DESCRIPTION OF THE DRAWINGS

FIG. 1 is a cross sectional view of a configuration of a plasma film forming apparatus in accordance with a first embodiment of the present invention;

FIG. 2 presents a graph showing an angle dependency of sputter etching;

FIG. 3 provides a graph showing a relationship between a bias power and a film forming rate on a wafer surface;

FIGS. 4A to 4G set forth partial enlarged cross sectional views of a target object to describe a series of processes of a film forming method in accordance with a first embodiment of the present invention;

FIG. 5 depicts a graph to describe a verticality of metal ions corresponding to a bias power and a process pressure respectively;

FIG. 6 illustrates a partial enlarged cross sectional view of a target object to describe a series of processes of a film forming method in accordance with a second embodiment of the present invention;

FIG. 7 offers an explanatory diagram to explain a use of a target object of the film forming method in accordance with the second embodiment of the present invention; and

FIGS. 8A to 8C illustrate a conventional process of filling recesses of a semiconductor wafer.

### DESCRIPTIONS OF REFERENCE NUMERALS

| | |
|---|---|
| 2: recess | 4: barrier layer |
| 6: seeding film (seeding film) | 8: metal film |
| 12: film forming apparatus | 14: processing vessel |
| 20: mounting table | 22: electrostatic chuck |
| 38: bias power supply | |
| 40: bias power supply controller | |
| 46: plasma generating device | 48: induction coil |
| 50: high frequency power supply | 56: metal target |
| 62: gas nozzle (gas introduction unit) | |
| 74: metal film | |
| S: semiconductor wafer (target object to be | |
| processed) | |
| S2: target object to be processed | |

### DETAILED DESCRIPTION OF THE EMBODIMENTS

Hereinafter, a film forming method and a film forming process in accordance with embodiments of the present invention will be described with reference to the accompanying drawings.

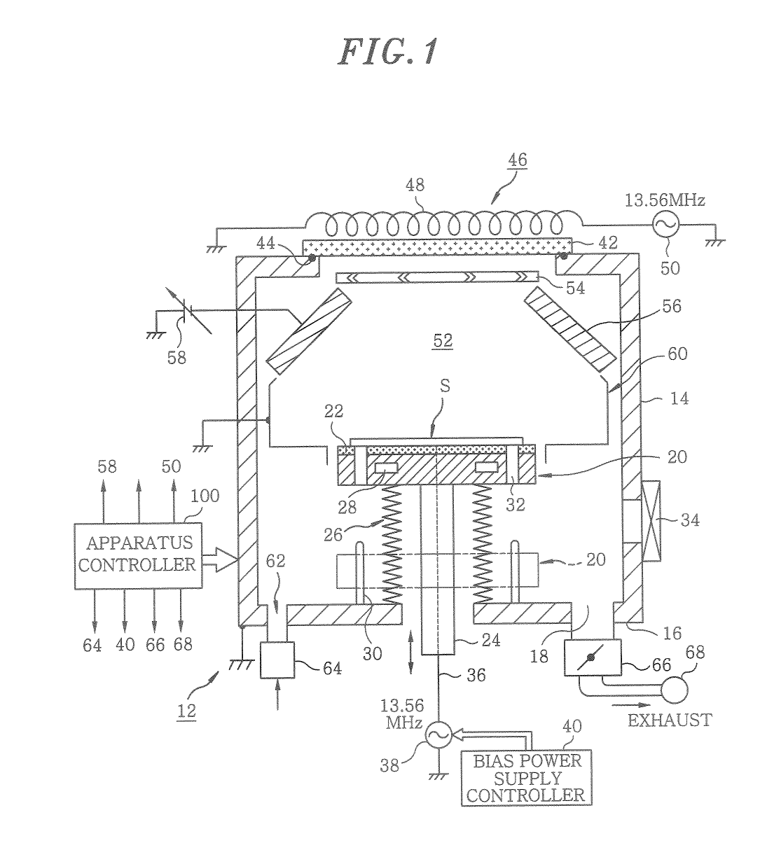

FIG. 1 is a cross sectional view showing an exemplary configuration of a plasma film forming apparatus in accordance with an embodiment of the present invention. Here, an inductively coupled plasma (ICP) sputtering apparatus is exemplified as the plasma film forming apparatus. As shown in FIG. 1, the film forming apparatus 12 includes a cylindrical processing vessel 14 made of, e.g., aluminum or the like. The processing vessel 14 is grounded. A gas exhaust port 18 is provided at a bottom portion 16 of the processing vessel 14, and a vacuum pump 68 is connected to the gas exhaust port 18 via a throttle valve 66.

A disk-shaped mounting table 20 made of, e.g., aluminum is disposed in the processing vessel 14. Disposed on the top surface of the mounting table 20 is an electrostatic chuck 22 for attracting and holding thereon a semiconductor wafer S which is a target object to be processed. A DC voltage is applied to the electrostatic chuck 22 for the attraction of the wafer S. The mounting table 20 is supported by a support 24 which is extended downward from the center of the bottom surface of the mounting table 20. The support 24 is connected to an elevation mechanism (not shown) through the bottom portion 16 of the processing vessel 14. Accordingly, by operating the elevation mechanism, the mounting table 20 can be moved up and down.

An extensible and contractible metallic bellows 26 is configured to surround the support 24. An upper end of the metallic bellows 26 is airtightly adjoined to the bottom surface of the mounting table 20, while a lower end of the metallic bellows 26 is airtightly fastened to the top surface of the bottom portion 16. The metallic bellows 26 allows the mounting table 20 to move up and down, while sealing the processing vessel 14 airtightly. A coolant path 28 for flowing a coolant for cooling the wafer W is formed inside the mounting table 2. The coolant is introduced into the coolant path 28 via a flow passage (not shown) inside the support 24 and is discharged from the coolant path 28 after circulating therein. A plurality of, e.g., three support pins 30 (only two are shown in FIG. 1) are installed upright from the bottom portion 16 of the processing vessel, and pin holes 32 are formed in the mounting table 20 at locations corresponding to the support pins 30.

If the mounting table 20 is moved down, the upper ends of the support pins 30 are protruded from the mounting table 20 through the pin holes 32, and, in this state, a transfer of the wafer S is carried out between a transfer arm (not shown) intruded into the processing vessel 14 and the support pins 30. A gate valve 34 is provided at a lower sidewall of the processing vessel 14, and while the gate valve 34 is opened, the transfer arm is allowed to enter the processing vessel 14. To apply a bias power to the mounting table 20, a bias power supply 38 made up of a high frequency power supply for generating a high frequency power of, e.g., about 13.56 MHz is connected to the electrostatic chuck 22 via a wiring 36. The bias power outputted from the bias power supply 38 is controlled by a bias power supply controller 40 made up of, e.g., a micro computer.

A high frequency power transmitting plate 42 made of a dielectric material such as aluminum nitride is airtightly installed at a ceiling opening of the processing vessel 14 via a seal member 44 such as an O-ring. Above the transmitting plate 42, there is provided a plasma generating device 46 for generating a plasma of a plasma gas, e.g., an Ar gas, in a processing space 52 inside the processing vessel 14. The plasma generating device 46 includes an induction coil 48 disposed above the transmitting plate 42 and a high frequency power supply 50 of, e.g., 13.56 MHz for plasma generation, which is connected to the coil 48.

A baffle plate 54 made of, e.g., aluminum is provided directly beneath the transmitting plate 42 to diffuse a high frequency which is introduced into the processing vessel 14 through the transmitting plate 42. Further, disposed below the baffle plate 54 to surround the upper region of the processing space 52 is an annular metal target 56 whose diameter decreases from the bottom to the top. The inner peripheral surface of the metal target 56 is of a conical surface shape of a truncated cone. A variable DC power supply 58 is connected to the metal target 56. For example, such a metal as tantalum metal or copper can be employed as the metal target 56. The metal target 56 is sputtered by Ar ions in the plasma, whereby metal atoms or metal atom groups are emitted from the metal target 56. The metal atoms or the metal atom groups become metal ions by being ionized while passing through the plasma.

Further, a cylindrical protection cover 60 made of, e.g., aluminum is disposed below the metal target 56 to surround the processing space 52. The protection cover 60 is grounded, and the lower portion thereof is bent inward to be extended to the vicinity of the sidewall of the mounting table 20. A gas inlet port 62 for introducing a processing gas into the processing vessel 14 is provided at a bottom portion of the processing vessel 14. A plasma gas, e.g., an Ar gas is supplied from the gas inlet port 62 via a gas control unit 64 including a mass flow controller, a valve, and the like.

Functional components of the film forming apparatus 12, specifically, the bias power supply controller 40, the high frequency power supply 50, the variable DC power supply 58, the gas controller 64, the throttle valve 66, the vacuum pump 68, and so forth are all connected to an apparatus controller 100 made up of, e.g., a computer. The apparatus controller 100 controls these functional components and allows the film forming apparatus 12 to perform a series of processes as follows.

First, the processing vessel 14 is turned into a vacuum state by operating the vacuum pump 68, and an Ar gas is flown into the processing vessel 14 via the gas control unit 64. Then, by controlling the throttle valve 66, the inner pressure of the processing vessel 14 is maintained at a specific vacuum level. Thereafter, a DC power is applied to the metal target 56 by the variable DC power supply 58, and a high frequency power is applied to the induction coil 48 by the high frequency power supply 50.

Further, the apparatus controller 100 also sends an instruction to the bias power supply controller 40 such that a specific bias power is applied to the mounting table 20, whereby the Ar gas is activated to generate a plasma by the powers applied to the metal target 56 and the induction coil 48. Ar ions in the plasma collide with the metal target 56, so that the metal target 56 is sputtered. Metal atoms and metal atomic groups emitted from the metal target 56 are ionized and converted into metal ions while passing through the plasma. The metal ions are attracted to the mounting table 20 to which the bias powers are applied, and finally deposited on the wafer S loaded on the mounting table 20.

If a greater bias power is applied to the mounting table, the Ar ions in the plasma as well as the metal ions are attracted to the mounting table 20, so that the deposition of the metal and the sputter etching are performed at the same time.

The apparatus controller 100 controls each functional component of the film forming apparatus 12 such that the formation of the metal film is carried out according to a process recipe, by executing control programs stored in a storage medium (e.g., a hard disk drive (HDD)) included in the apparatus controller 100. The control programs may be stored in a storage medium such as a floppy (registered trademark) disk (FD), a compact disk (CD), a flash memory, or the like. In such a case, the apparatus controller 100 controls each functional component by executing the control programs retrieved from the storage medium.

Now, a film forming method, which is performed by the film forming apparatus 12, in accordance with embodiments of the present invention will be described.

### First Embodiment

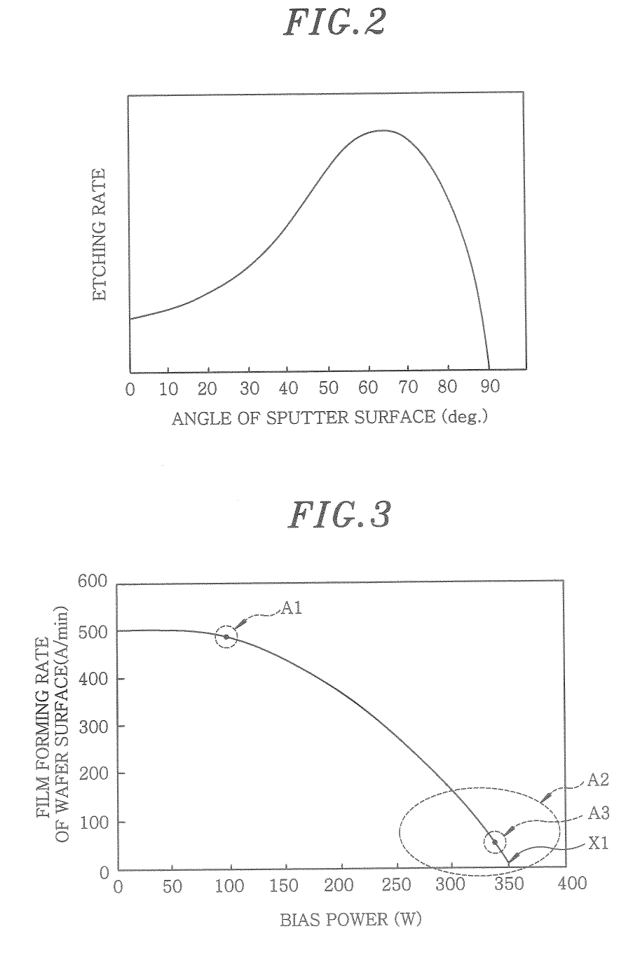

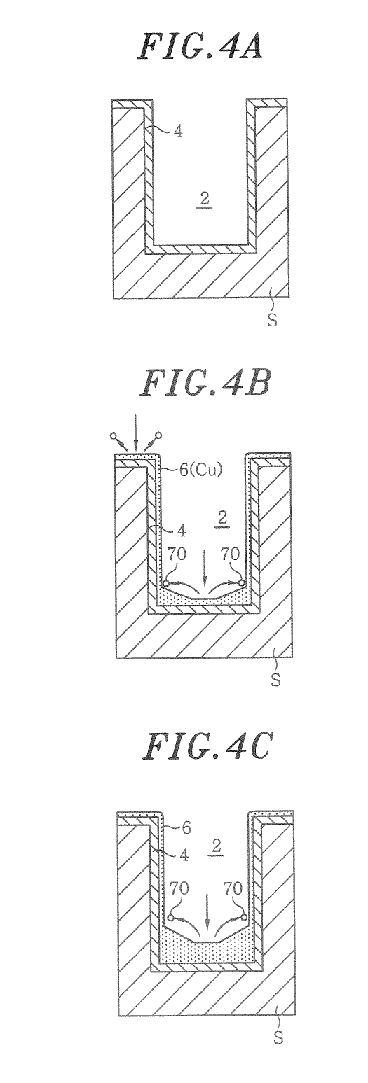

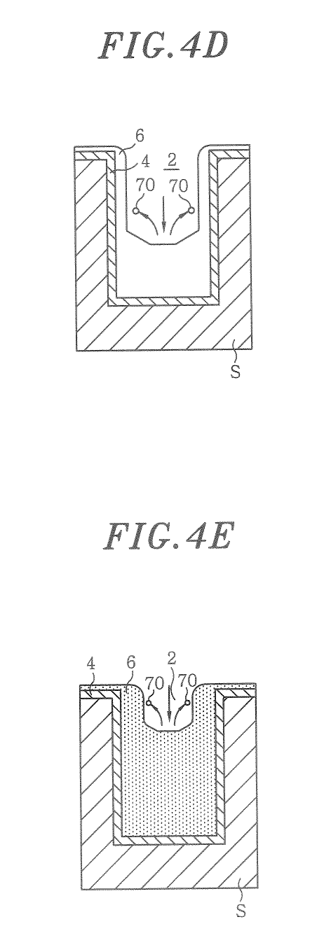

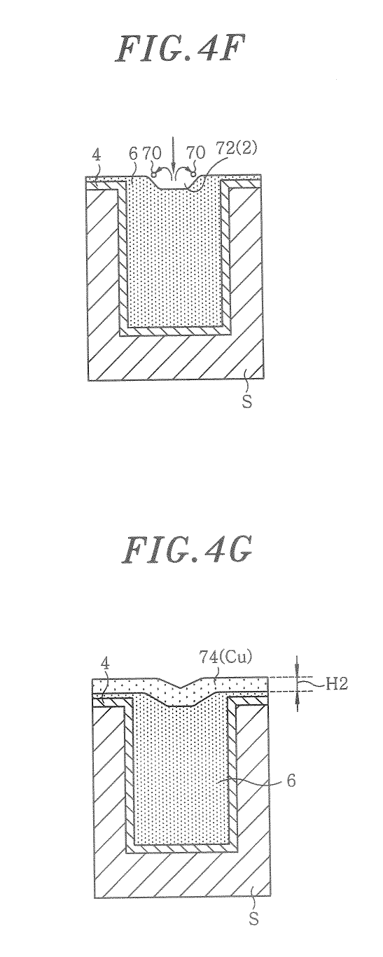

FIG. 2 sets forth a graph showing an angle dependency of sputter etching; FIG. 3 provides a graph showing a relationship between a bias power and a film forming rate on a wafer surface; and FIGS. 4A to 4G present diagrams illustrating a series of processes of the first embodiment. The technical characteristic of the first embodiment of the present invention has features to realize a state in which a deposition rate of a metal film by an attraction of metal ions and an etching rate of a sputter etching by ions originated from a plasma gas (e.g., Ar ions) are substantially balanced, by controlling a bias power level appropriately when performing a film formation by plasma sputtering. In this case, filling a recess with a metal is realized by a metal film mainly deposited on the sidewall of the recess.

Specifically, the bias power is set such that the deposition rate of the metal film and the sputter etching rate are substantially balanced at a “wafer surface” (surface of a target object to be processed), which is a plane surface perpendicular to an imaginary central axis line of the annular metal target 56 and located at the same height as that of an opening entrance of the recess. Here, it is to be noted that the term “wafer surface” is used to refer to the surface of the wafer on which a film is to be formed, except the inner surface (sidewall surface and bottom surface) of the recess.

This will be described in more detail. Here, the etching rate of the sputter etching will be first explained, without considering the deposition of the metal film. FIG. 2 is a graph showing a relationship between an angle of a sputter surface (which means a sputtered surface) and an etching rate. Here, the angle of the sputter surface angle refers to an angle formed between a normal of the sputter surface and an incident direction of ions (specifically, Ar ions) which arrive at the sputter surface to sputter it. For example, the angle of the sputter surface at the wafer surface and at the bottom surface of the recess is 0°, while the angle of the sputter surface at the sidewall surface of the recess is 90°.

As can be clearly seen from the graph, the sputter etching is somewhat performed on the wafer surface (at which the angle of the sputter surface is 0°), while it rarely occurs on the recess's sidewall surface (at which the angle of the sputter surface is 90°). Further, the recess's opening edge portion (at which the angle of the sputter surface ranges from about 40° to 80°) is sputtered very severely.

FIG. 3 provides a graph showing a relationship between a bias power applied to the mounting table 20 on which the wafer S is loaded and a metal film forming rate (i.e., a metal film growing rate or a metal film thickness increasing rate) on the wafer surface (at which the angle of the sputter surface is 0°) in the plasma filming forming apparatus configured as the ICP sputtering apparatus shown in FIG. 1. When a high frequency power for plasma generation is maintained constant, a metal deposition by the attraction of metal ions is dominant if the bias power is not so great, so that a high film forming rate is obtained. If the bias power becomes great, however, a sputtering effect by ions, which are originated from a plasma gas and accelerated by the bias power, increases, and, as a result, a metal film once deposited is removed by the sputter etching. This sputter etching effect is increased as the bias power increases.

Accordingly, if the deposition rate of the metal film (when assuming that no etching occurs) is equal to the etching rate, the deposition and the etching are offset by each other, so that the metal film forming rate, i.e., the metal film thickness increasing rate at the wafer surface becomes zero (see the point X1 (bias power 350 W) in the graph of FIG. 3). The graph of FIG. 3 shows an exemplary relationship between the bias power and the film forming rate, and values of the graph would be varied depending on the film forming apparatus or a film forming time period taken for the film formation.

Conventionally, when performing a film formation by using such a sputtering apparatus, a high film forming rate is obtained without setting the bias power to be excessively great (see the region A1 of FIG. 3). In the embodiment of the present invention, however, the bias power is set to a level (corresponding to the range A2 of FIG. 3) at which the metal deposition rate and the sputter etching rate are substantially balanced. Here, the conception of the “substantial balance” includes a case where a metal film is formed at a low film forming rate corresponding to about 3/10 of that in the region A1 of FIG. 3 at the highest as well as a case where the film forming rate on the wafer surface is zero.

In addition to the basic principal of the present invention as described above, a detailed description of the present method will now be provided.

First, while the mounting table 20 is at a lowered position, a wafer S is loaded into the processing vessel 14 through the gate valve 34 and is held on the support pins 30. Then, the mounting table 20 is moved upward, and the wafer S is placed on the top surface of the mounting table 20. The wafer S is attracted and held on the mounting table 20 by an electrostatic adsorptive force of the electrostatic chuck 22.

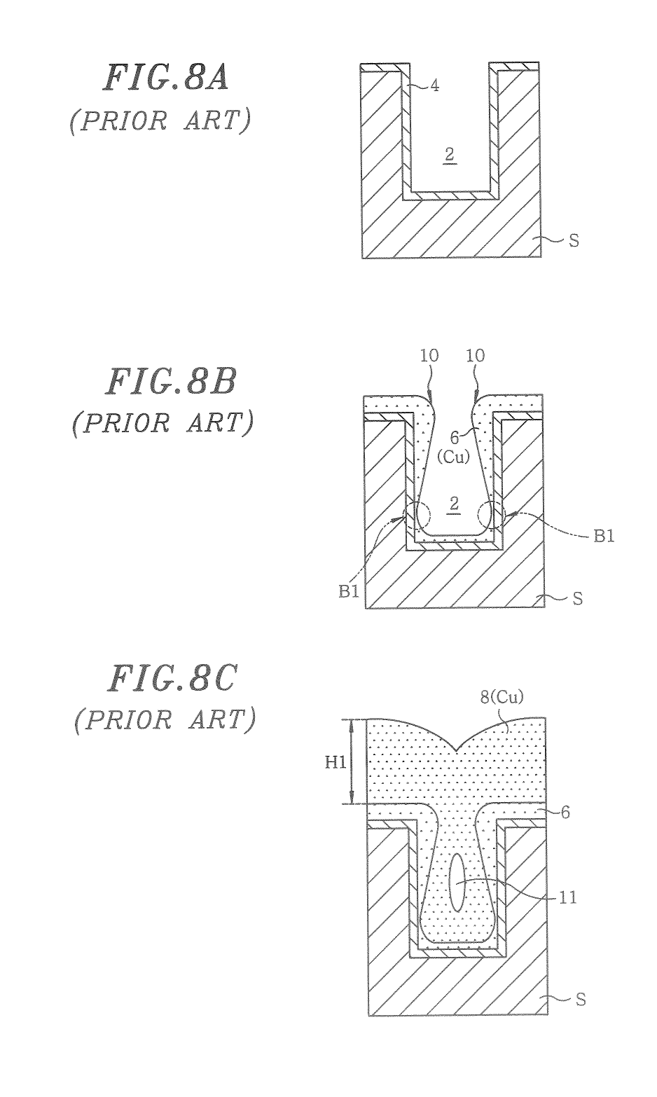

The wafer S has a recess 2 (see FIGS. 8A to 8C) such as a via hole, a through hole and/or a groove opened at the surface thereof. Further, a barrier layer 4 made of a laminated structure of TaN/Ta films is previously formed on the wafer surface and the inner surface of the recess 2 through a sputtering process using Ta as a metal target, which is performed by another plasma film forming apparatus having the same configuration as shown in FIG. 1 (See FIG. 4A). The width (for a groove) and the diameter (for a hole) of the recess 2 is very minute, i.e., no greater than several hundred nanometers. Further, the aspect ratio of the recess 2 is about 5 at maximum.

Then, a film forming process is started. Here, copper is used as the metal target 56. After vacuum evacuating the processing vessel 14 to a specific pressure level, a high frequency voltage is applied to the induction coil 48 of the plasma generating device 46, and a bias power is applied to the electrostatic chuck 22 of the mounting table 20 from the bias power supply 38. Then, a plasma gas e.g., an Ar gas is supplied into the processing vessel 14 from the gas inlet port 62.

In the film forming process the bias power is set to be in the region A2 of FIG. 3. For example, in order to set the film forming rate on the wafer surface to be substantially zero, a formation of a metal film (a Cu film) is performed by setting the bias power to a value corresponding to the point X1 of FIG. 3 or to a value in the range A3 slightly lower than the point X1. The bias power is specifically set to range from 320 to 350 W, and only the Ar gas is supplied from the gas inlet port 62. As a result, as shown in FIG. 4B, a metal film 6 made of a Cu film is deposited on the sidewall surface and the bottom surface of the recess 2 in a substantially uniform manner, while it hardly deposits on the wafer surface.

If the film forming process is continued while keeping the bias power at the above-specified power level, substantially no metal film grows on the wafer surface, or the metal film 6 grows thereon at a very low film forming rate. On the other hand, on the sidewall surface of the recess, the metal film 6 gradually grows with a uniform film thickness, and the metal film 6 also grows gradually on the bottom surface of the recess 2. As a result, the recess 2 is filled with the metal without generating a void.

The reason is explained as follows. By setting the bias power within the above-specified power range, a substantial balance is kept between the metal deposition rate and the sputter etching rate on the wafer surface perpendicular to the incident direction of the metal ions. As a result, the film forming rate of the metal film substantially becomes zero or becomes very small on the wafer surface. Further, in case the width or the diameter of the recess 2 is very minute no larger than about several hundred nanometers, scattering metals 70 sputtered from the bottom portion of the recess 2 adhere to the bottom sidewall surface of the recess 2. Thus, it is possible to deposit the metal film 6 on the bottom sidewall surface of the recess 2, which has been difficult in a conventional method. As a result, the film thickness of the sidewall surface of the recess 2 can be made uniform in a depth direction.

Moreover, since the metal film 6 adhered on the bottom sidewall surface of the recess 2 is gradually expanded toward a central portion of the recess 2, the metal film 6 also gradually accumulates on the bottom portion of the recess 2. As a result, the recess 2 is filled from the bottom side thereof as well. Further, the reason why no overhang portion 10 (see FIG. 8C) is formed at the opening portion of the recess 2 is that the deposition and the etching offset each other.

In the above film forming process in which the metal deposition rate and the sputter etching rate are substantially balanced, it is important to set up an environment in which almost all (90% or more, and preferably 99% or more) of the metals sputtered from the metal target are ionized and converted into metal ions while passing through the plasma such that substantially no neutral metal atom arrives at the wafer S. For the purpose, it is preferable to set the high frequency power applied to the induction coil 48 of the plasma generating device 46 to be high (ranging from about 5000 to 6000 W).

If film forming species contain neutral metal atoms, though it is possible to make the film forming rate on the wafer surface zero, an etching rate at the bottom portion of the recess 2 exceeds a film deposition rate thereat. As a result, the underlying barrier layer 4 may be damaged at the bottom portion of the recess 2, which is not preferable. The reason why the etching becomes more dominant than the film deposition is explained as follows. The neutral metal atoms can contribute to the film deposition by reaching the wafer surface, but they cannot reach as far as the bottom portion of the recess 2 because of their low verticality. Thus, at the bottom portion of the recess 2, the number of ions (Ar ions) causing the sputtering exceeds the number of the metal atoms. Here, for the simplicity of explanation, it is assumed that a single metal atom (or a metal ion) is sputtered (etched) from a deposited film by a single ion in the plasma.

Further, in the film forming method in accordance with the embodiment of the present invention, since the metal film is deposited on the sidewall surface of the recess 2, it is preferable that the metal ions have a low verticality for the wafer. For the purpose, the inner pressure of the processing vessel 14 is maintained at a level higher than that in the conventional film forming method and is set to be in a low vacuum state (1 to 100 mTorr, and, more preferably, 3 to 10 mTorr), to thereby shorten a mean free path of the metal ions. As a result, the number of the collisions of the metal ions with the plasma ions increases, and the verticality of the metal ions for the wafer can be reduced.

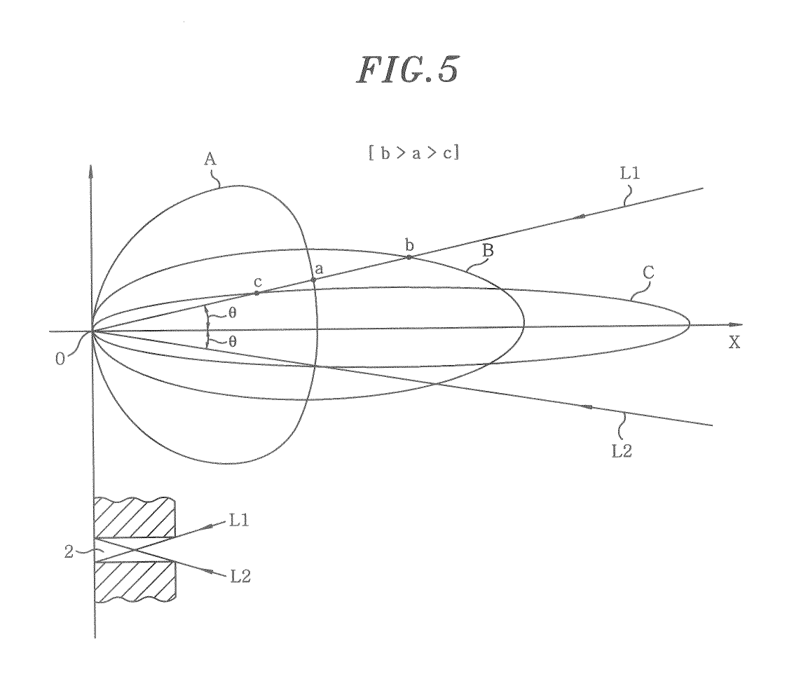

This will be further explained with reference to FIG. 5. FIG. 5 is a graph showing a verticality of metal ions in relation with a bias power and a process pressure. Each of ellipses A to C indicates a relationship between the amount of metal ions deposited on a unit area of the wafer surface and an incident angle thereat. That is, when a straight line is drawn from the origin O to cross the ellipses, a distance from the origin O to each of the intersection points (a, b, c) indicates an amount of metal ions, and an angle formed by the straight line and the X-axis indicates their incident angle.

Here, it should be noted that when metal ions are vertically incident on the wafer surface, their incident angle is 0°. For example, the ellipse A represents a case of performing a film formation under a bias power condition corresponding to the region A1 of FIG. 3; the ellipse B indicates a case of performing a film formation under a bias power condition corresponding to the point X1 of FIG. 3 at a low-vacuum process pressure; and the ellipse C represents a case of performing a film formation under a bias power condition corresponding to the point X1 of FIG. 3 (0.5 mTorr or less) at a high-vacuum process pressure. Moreover, each of straight lines L1 and L2 in FIG. 5 represents metal ions incident on the wafer at a critical angle θ which is a maximum incident angle of metal ions that can reach the bottom portion of the recess 2, as also indicated in a lower part of FIG. 5.

In FIG. 5, metal ions reaching the wafer S at an incident angle smaller than the critical angle θ are deposited on the bottom surface of the recess 2 as well as on the sidewall surface thereof. Meanwhile, metal ions reaching the wafer S at an incident angle larger than the critical angle θ are only deposited on the sidewall surface of the recess, and as the incident angle increases, they tend to be deposited primarily on an upper portion of the sidewall surface of the recess. Accordingly, in order to uniformly deposit a film on the entire sidewall of the recess, it is preferable to perform the film formation by using metal ions having a verticality represented by the ellipse A rather than using meal ions having a verticality represented by the ellipse C, and it is more preferable to use metal ions having a verticality expressed by the ellipse B. This is because the more the amount of metal ions incident on the wafer S at an incident angle near the critical angle θ is, the better the film formation is carried out.

It is preferable to set the bias power level not to be excessively great lest the barrier layer 4 formed of TaN/Ta films should be damaged by the sputtering of the ions (Ar ions) in the plasma.

Further, it is preferable to connect the plasma film forming apparatus 12 having the metal target of copper to a plasma film forming apparatus (for forming a barrier layer) having a metal target of tantalum via a vacuum transfer chamber. With such arrangements, the semiconductor wafer S, on which the barrier layer 4 is formed, can be transferred into the plasma film forming apparatus 12 without being exposed to the atmosphere.

Referring back to FIG. 4, as the deposition of copper progresses, the almost entire portion of the recess 2 is filled with the copper with a slightly depressed portion 72 left on a central top surface portion of the copper (i.e., the metal film 6) buried in the recess 2 as shown in FIG. 4F. The film forming process is finished in this state.

Then, the wafer S is unloaded from the plasma processing apparatus 12, and a plating process is performed on the wafer S. Specifically, as illustrated in FIG. 4G, a metal film 74 made of the same metal as that of the metal film 6 (copper in this embodiment) is deposited on the entire top surface of the wafer S to fill the depressed portion 72 completely. The depressed portion 72 is much shallower than the recess 2 shown in FIGS. 8A to 8C which is to be filled with a metal by the plating process in the conventional example, so that a special plating process such as a ternary plating is not necessary and the filling of the depressed portion 72 can be carried out by a simple plating process, e.g., a binary plating process using smaller number of additives.

Further, as shown in FIG. 4G, since the thickness H2 of the metal film 74 formed by the plating process is much thinner than the thickness H1 of the metal film 8 shown in FIG. 8C, a polishing process for removing excessive films can be simply performed for a shorter period of time.

### Second Embodiment

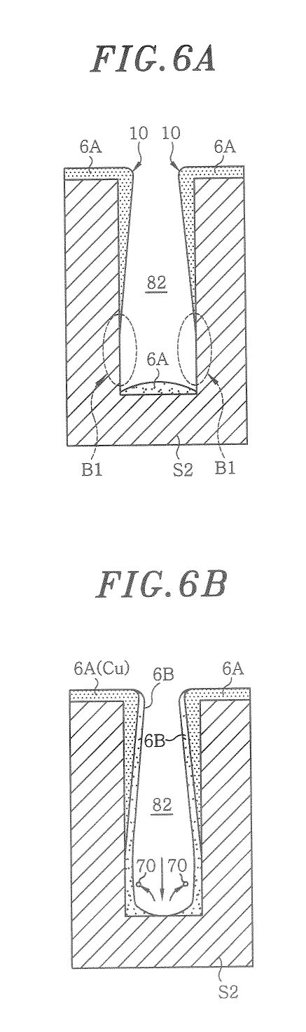

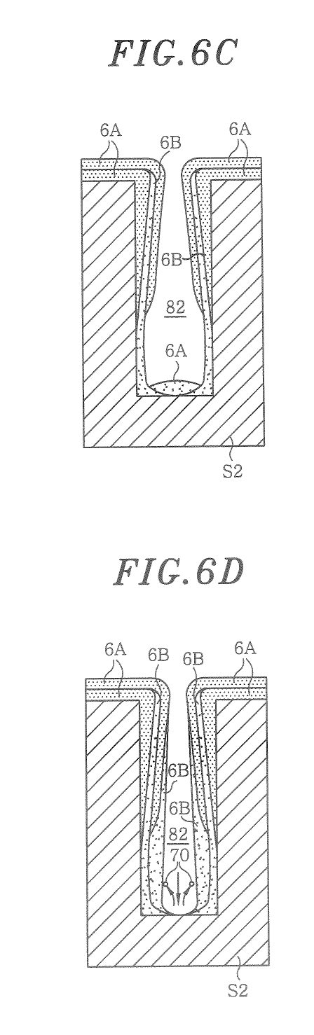

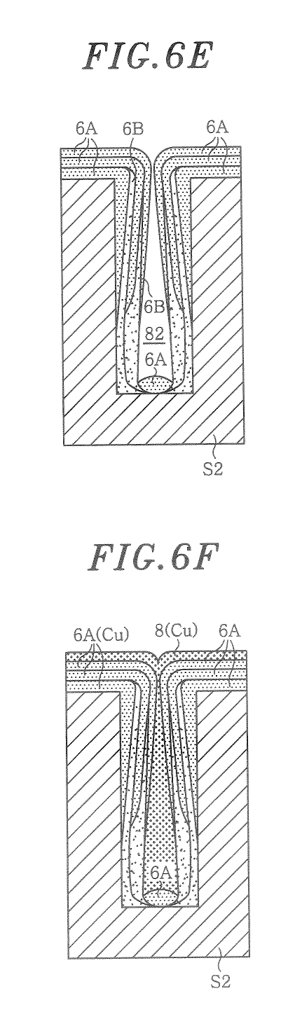

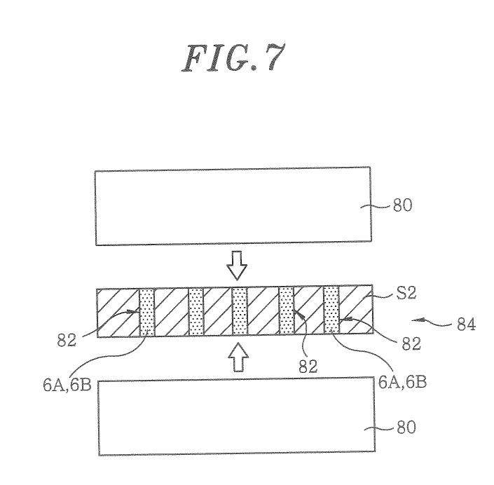

The above-explained first embodiment is advantageous when it is applied to a case where the width (in case of a groove) or the diameter (in case of a hole) of the recess 2 is very minute, no larger than several hundred nanometers. However, when the width or the diameter of a recess is much larger than that, e.g., 20 to 100 μm, an efficient filling of the recess with a metal is possible by combining a film formation under the process condition of the first embodiment and a film formation under a different process condition. Below, a film forming method in accordance with a second embodiment of the present invention will be described. FIGS. 6A to 6F are partial enlarged cross sectional views showing a series of processes of the second embodiment, and FIG. 7 sets forth a diagram to explain a use of an object processed by the film forming method in accordance with the second embodiment of the present invention.

As shown in FIG. 7, a target object S2 is made of, e.g., a semiconductor wafer such as a silicon substrate or a polymer resin such as a polyimide resin. The target object S2 is a substrate for an interposer 84 placed between, e.g., IC chips 80 to allow, e.g., a conduction therebetween when the IC chips 80 are laminated on and adjoined to each other. The target object S2 is provided with a plurality of recesses 82 having a large width or diameter, and a metal, e.g., copper is buried in the recesses 82. Each recess 82 has a considerably high aspect ratio of, e.g., 5 or greater, which is considerably large. After the series of processes illustrated in FIGS. 6A to 6F are completed, the object S2 is cut at the bottom sides of the recesses 82, so that the state shown in FIG. 7 is obtained. In FIGS. 6A to 6F, a barrier layer is omitted.

Since each recess 82 has a width or a diameter much larger than that of the recess 2 of the first embodiment, it takes a long time to fill the recess 82 under the process condition of the first embodiment featuring a low film forming rate, so that it is impractical. Thus, in the second embodiment, a formation of a metal film, e.g., a copper film as a seed film on the inner surface of the recess 82 including its sidewall surface is conducted by combining the process condition (bias power) employed in the first embodiment and the process condition (bias power) employed in the prior art.

As shown in FIG. 6A, as a first film forming process, a metal film 6A made of a copper film is formed as a seed film under the same process condition as that for a conventional film forming method using a plasma sputtering. At this time, the bias power is set to have a value that falls within the region A1 of FIG. 3. That is, the bias power is set to obtain a metal deposition rate much greater than a sputter etching rate on the surface of the target object. In this case, a metal film hardly deposits on a lower area B1 of the sidewall surface of the recess 82, though the metal film 6A deposits on the bottom surface of a recess 82, as explained earlier with reference to FIG. 8B.

After performing the first film forming process for a specific period of time, a second film forming process is conducted as illustrated in FIG. 6B. In the second film forming process, the same process condition (bias power) as that employed in the first embodiment is utilized. That is, in the second film forming process, the bias power is set to have a value that falls within the region A2 of FIG. 3, e.g., a value corresponding to the point X1 in the region A3, to realize a substantially balanced state between the film deposition rate and the sputter etching rate.

As explained before with reference to FIGS. 4A to 4G, a metal film 6B made of a copper film is deposited as a seed film on the inner surface of the recess 82. At this time, the metal film 6A deposited on the bottom portion of the recess 82 in the first film forming process is struck and scattered by plasma ions (Ar ions), and the scattering metals 70 are attached to and deposited on the adjacent sidewall area B1 of the recess 82. Accordingly, through the second film forming process, the thin metal films 6A and 6B are deposited on the entire sidewall surface of the recess 82. Since the thicknesses of the metal films 6A and 6B formed by a single performance of the first and the second film forming process are very thin, the first and the second film forming process are repeated alternately (see FIGS. 6C and 6D). In the shown example, the first film forming process was conducted three times, and the second film forming process was conducted two times. However, the repetition number of each process is not limited thereto but can be determined by considering a throughput.

In the second film forming process, since the metal film on the bottom surface of the recess 82 is struck and dispersed by sputtering, a metal film may hardly be present on the bottom surface of the recess 82 immediately after the second film forming process. Thus, the alternative repetition of the first and the second film forming process is completed by the first film forming process, as shown in FIG. 6E.

After the film forming process by the plasma sputtering is completed, a plating process is performed, as illustrated in FIG. 6F, whereby the recess 82 is filled with a metal film 8 such as a copper film. In FIG. 6E, though the opening of the recess 82 is show to be narrow, the size of the opening is actually much larger than the thickness of the metal film formed on the inner surface of the recess 82. Thus, there is no case where a void is formed when filling the recess 82 by plating.

After completing the filling of the recess 82, the target object S2 is subjected to a polishing process in which unnecessary metal films present on the top surface of the target object S2 are removed. Then, the target object S2 is cut along a cross section including the bottom surface of the recess 82, whereby the interposer 84 shown in FIG. 7 is obtained. It is preferable to form grooves for interconnection in the surface of the interposer 84 and fill the grooves with a metal by the above-described film forming method.

The target object S2 is not limited to the substrate for the interposer 84. For example, an induction coil can be fabricated by forming spiral grooves (recesses) in the top surface of a target object and filling the grooves with a metal by using the film forming method in accordance with the first or the second embodiment of the present invention.

Further, values specified in the above embodiments are provided for illustrative purpose only, and they may be varied. Further, though the above embodiments have been described for the case of using copper as a buried material, the buried material is not limited thereto. For example, Al, W, Ti, Ru, Ta or the like may be employed instead.

Moreover, the frequency of the high frequency power supplies is not limited to 13.56 MHz, and they may be of a frequency of, e.g., 27.0 MHz. Further, the inert gas for plasma generation is not limited to the Ar gas, but another inert gas such as He and Ne can be employed instead. Also, the target object is not limited to the semiconductor wafer, either. For example, an LCD substrate, a glass substrate or the like may be employed as the target object.

What is claimed is:

1. A film forming method comprising the steps of:
loading a target object on a mounting table in a vacuum processing vessel, the target object having a recess opened at a surface thereof;
generating a plasma in the vacuum processing vessel and generating metal ions by sputtering a metal target by the plasma, the metal target being disposed in the vacuum processing vessel; and
applying a bias power to the mounting table to attract the metal ions into the recess to be deposited therein, thereby filling the recess with the metal;
wherein the bias power is set to a level which makes a deposition rate of a metal deposition by the attraction of the metal ions and an etching rate of a sputter etching by the plasma substantially balanced at the surface of the target object.

2. The film forming method of claim 1, wherein a plating process is performed after the filling of the recess with the metal.

3. The film forming method of claim 2, wherein a polishing process for polishing and flattening the surface of the target object is performed after the plating process.

4. The film forming method of claim 1, wherein a width or a diameter of the recess is 100 nm or less, and the aspect ratio of the recess is 3 or higher.

5. The film forming method of claim 1, wherein the metal is copper, aluminum or tungsten.

6. A film forming method comprising:
a loading process for loading a target object on a mounting table in a vacuum processing vessel, the target object having a recess opened at a surface thereof;
a first film forming process including the steps of generating a plasma in the vacuum processing vessel and generating metal ions by sputtering a metal target by the plasma, the metal target being disposed in the vacuum processing vessel; and applying a bias power to the mounting table to attract the metal ions into the recess to be deposited therein, thereby filling the recess with the metal; and
a second film forming process including the steps of generating a plasma in the vacuum processing vessel and generating metal ions by sputtering the metal target by the plasma; and applying a bias power to the mounting table to attract the metal ions into the recess to be deposited therein, thereby filling the recess with the metal,
wherein the first film forming process and the second film forming process are alternately repeated plural times, and the bias power of the first film forming process is set to a level which makes a deposition rate of a metal deposition by the attraction of the metal ions much higher than an etching rate of a sputter etching by the plasma on the surface of the target object, and the bias power of the second film forming process is set to a level which makes the deposition rate of the metal deposition by the attraction of the metal ions and the etching rate of the sputter etching by the plasma substantially balanced at the surface of the target object.

7. The film forming method of claim 6, wherein the alternative repetition of the first and the second film forming process is completed by the first film forming process.

8. The film forming method of claim 6, wherein a plating process is performed after repetitively performing the first and the second film forming process plural times.

9. The film forming method of claim 8, wherein a polishing process for polishing and flattening the surface of the target object is performed after the plating process.

10. The film forming method of claim 6, wherein the target object is a substrate for an interposer connecting IC chips to each other.

11. The film forming method of claim 6, wherein an induction coil is formed by a metal film buried in the recess of the target object.

12. The film forming method of claim 6, wherein the metal is copper, aluminum or tungsten.

13. A plasma processing apparatus comprising:
a vacuum processing vessel to be evacuated;
a gas introduction unit for introducing a gas into the processing vessel;
a mounting table for mounting thereon a target object which has a recess opened at a surface thereof;
a plasma generating device for generating a plasma in the processing vessel;
a metal target disposed in the processing vessel, to be ionized by the plasma;
a bias power supply for supplying a bias power to the mounting table; and
a bias power supply controller for controlling the bias power supply,
wherein the bias power supply controller controls the bias power output from the bias power supply to a level which makes a deposition rate of a metal deposition by the attraction of metal ions and an etching rate of a sputter etching by the plasma substantially balanced at the surface of the target object.

14. A plasma processing apparatus comprising:
a vacuum processing vessel to be evacuated;
a gas introduction unit for introducing a gas into the processing vessel;
a mounting table for mounting thereon a target object which has a recess opened at a surface thereof;
a plasma generating device for generating a plasma in the processing vessel;
a metal target disposed in the processing vessel, to be ionized by the plasma;
a bias power supply for supplying a bias power to the mounting table; and
a bias power supply controller for controlling the bias power supply,
wherein the bias power supply controller controls the entire plasma processing apparatus to perform a process for activating the gas to generate the plasma and generating metal ions by sputtering the metal target by the plasma and a process for filling the recess with a metal film by applying a bias voltage which makes a deposition rate of a metal deposition by an attraction of the metal ions and an etching rate of a sputter etching by the plasma substantially balanced.
